(19) United States
(12) Patent Application Publication
(10) Pub. No.: US 2007/0099318 A1
(43) Pub. Date: May 3, 2007

(54) Mold for display device and method for manufacturing display device using the same

(75) Inventors: Jae-hyuk Chang, Gyeonggi-do (KR); Nam-seok Roh, Gyeonggi-do (KR); Mun-pyo Hong, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/592,110

(22) Filed: Nov. 1, 2006

(30) Foreign Application Priority Data
Nov. 2, 2005 (KR) 2005-0104510

(51) Int. Cl. H01L 21/00

(52) U.S. Cl. 438/22

(57) ABSTRACT

A method for manufacturing a display device, comprises; providing an insulating substrate; forming a passivation layer on the insulating substrate; arranging a mold including a supporting layer, a pattern forming layer provided on a first surface of the supporting layer and having concaves-convexes formed thereon and a buffer layer formed on the other surface of the supporting layer so that the pattern forming layer faces the passivation layer; and pressurizing the mold to form a concave-convex pattern corresponding to the concaves-convexes on the passivation layer. Thus, the present invention provides a method for manufacturing a display device being capable of enhancing the reproducibility and yield of the concave-convex pattern.

### CROSS-REFERENCE TO RELATED APPLICATIONS

This application claims priority from Korean Patent Application No. 2005-0104510, filed on Nov. 2, 2005 in the Korean Intellectual Property Office, the disclosure of which is incorporated herein by reference.

### FIELD OF INVENTION

The present invention relates to a method for manufacturing display devices and, more particularly, to the manufacture of reflective and transreflective display devices.

### DESCRIPTION OF THE RELATED ART

In general, a display device can be classified as a light-transmitting type, a transflective type or a reflection type. In the light-transmitting type of display, a backlight unit is disposed behind a display panel and light emitted from the backlight unit is transmitted through the panel. The reflection type display device uses outside light and eliminates the backlight unit which consumes 70% of the entire electric power of the device. The transflective type display device combines the advantages of both types of display, utilizing both outside light and the backlight unit to provide good brightness regardless of a variation of the ambient luminous intensity.

In the manufacture of the transflective type and the reflection type of display devices, a passivation layer is formed on a substrate on which a thin film transistor is formed and a concave-convex pattern is formed on the passivation layer. If the reflective layer is formed on the entire surface of the concave-convex pattern, the reflection type display device is obtained and, if the reflective layer is formed partially on the concave-convex pattern, the transflective type of device is obtained.

To make the concave-convex pattern, a mold on which concaves-convexes are formed is arranged on the passivation layer and pressurized to form the concave-convex pattern.

However, there are problems that it is sometimes difficult to separate the mold from the passivation layer causing the shape of the mold to become deformed, making for poor reproducibility of the concave-convex pattern. To reduce the deforming of the mold, a supporting layer may be formed on the other surface of the mold. However, the difference between the coefficients of thermal expansion of the supporting layer and other part of the mold tend to deform the mold into a dish shape which also makes for poor reproducibility. Further, the dish shape may prevent a portion of the passivation layer from being removed from the mold.

### SUMMARY OF THE INVENTION

Accordingly, it is an aspect of the present invention to provide a better method for molding the concave-convex pattern used in a reflective or transreflective display device. The method for manufacturing a display device, comprises; providing an insulating substrate; forming a passivation layer on the insulating substrate; arranging a mold including a supporting layer, a pattern forming layer provided on a first surface of the supporting layer and having concaves-convexes formed thereon and a buffer layer formed on the other surface of the supporting layer so that the pattern forming layer faces the passivation layer; and pressurizing the mold to form a concave-convex pattern corresponding to the concaves-convexes on the passivation layer.

According to an aspect of the present invention, the method for manufacturing the display device further comprises forming gate wires extended in a first direction on the insulating substrate and data wires intersecting insulatively gate wires to define a pixel area before forming the passivation layer; and forming a thin film transistor at an intersection area of gate wires and data wires, wherein the concaves-convexes are provided to correspond to at least a portion of the pixel area.

According to an aspect of the present invention, the thin film transistor comprises a source electrode and a drain electrode spaced apart from the source electrode to define a channel region, the pattern forming layer comprises a protrusion part protruded from a first surface of the pattern forming layer, and an end portion of the protrusion part is contacted with the drain electrode when the mold is pressurized.

According to an aspect of the present invention, the method for manufacturing the display device further comprises forming a pixel electrode on the passivation layer after removing the mold; and forming a reflective layer on at least some portion of the pixel electrode.

According to an aspect of the present invention, the passivation layer contains polymer and is cured by at least one of heat and light.

According to an aspect of the present invention, the passivation layer is cured when the mold is pressurized.

According to an aspect of the present invention, the pattern forming layer and the buffer layer comprise the same material.

According to an aspect of the present invention, a coefficient of thermal expansion of the buffer layer is substantially the same as that of the pattern forming layer.

According to an aspect of the present invention, a modulus of elasticity of the buffer layer is substantially the same as that of the pattern forming layer.

According to an aspect of the present invention, a value obtained from multiplying the thickness of the buffer layer by a coefficient of thermal expansion of the buffer layer is 80% to 120% of a value obtained from multiplying the thickness of the pattern forming layer by a coefficient of thermal expansion of the pattern forming layer.

According to an aspect of the present invention, the supporting layer comprises a film comprising at least one of polyethylene terephthalate (PET) and polycarbonate (PC)

According to an aspect of the present invention, the mold a transparent material through which light is transmitted.

The foregoing and/or other aspects of the present invention can be achieved by providing a mold for a display device, comprising: a supporting layer; a pattern forming layer provided on a first surface of the supporting layer and having concaves-convexes formed thereon; and a buffer layer formed on a second surface of the supporting layer.

According to an aspect of the present invention, the pattern forming layer and the buffer layer comprise the same material.

According to an aspect of the present invention, a coefficient of thermal expansion of the buffer layer is substantially the same as that of the pattern forming layer.

According to an aspect of the present invention, a modulus of elasticity of the buffer layer is substantially the same as that of the pattern forming layer.

According to an aspect of the present invention, a value obtained from multiplying the thickness of the buffer layer by a coefficient of thermal expansion of the buffer layer is 80% to 120% of a value obtained from multiplying the thickness of the pattern forming layer by a coefficient of thermal expansion of the pattern forming layer.

According to an aspect of the present invention, the concaves-convexes comprise a concave lens shape.

According to an aspect of the present invention, the concaves-convexes comprise an embossing shape.

According to an aspect of the present invention, the pattern forming layer further comprises a protrusion part protruded from the surface of the pattern forming layer.

According to an aspect of the present invention, the supporting layer is a film comprising at least one of polyethylene terephthalate (PET) and polycarbonate (PC)

According to an aspect of the present invention, the pattern forming layer, the supporting layer and the buffer layer comprise transparent material through which light is transmitted.

According to an aspect of the present invention, at least one of the pattern forming layer and the buffer layer comprise polydimethylsiloxane (PDMS).

### BRIEF DESCRIPTION OF THE DRAWINGS

The foregoing and other aspects and advantages of the prevent invention will become apparent from a reading of the ensuing description, together with the drawing, in which:

FIG. 1 is a view showing an arrangement of a thin film transistor substrate according to an embodiment of the present invention;

FIG. 2 is a sectional view, taken along line II-II in FIG. 1;

FIGS. 3A through FIG. 3C are sectional views sequentially illustrating a method for manufacturing the liquid crystal display device according to the embodiment of the present invention;

FIGS. 4a and FIG. 4b are sectional views of a conventional mold used for manufacturing a liquid crystal display device; and

FIG. 5a and FIG. 5b are sectional views of a mold used for manufacturing the liquid crystal display device according to the embodiment of the present invention.

### DESCRIPTION OF THE EMBODIMENTS

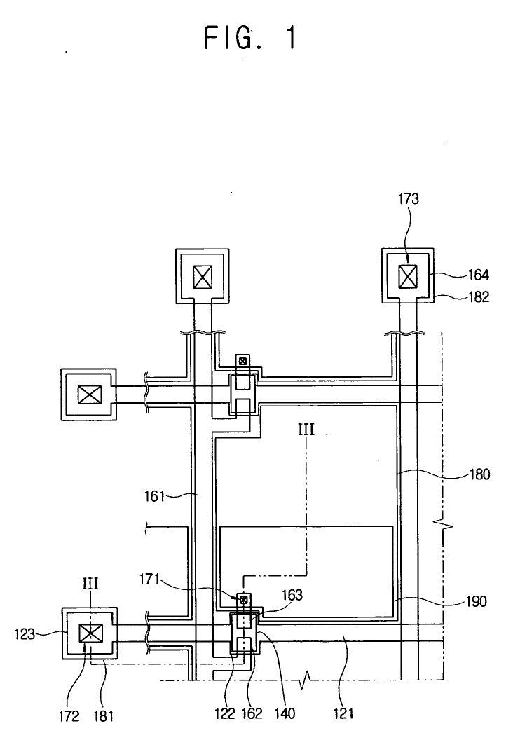

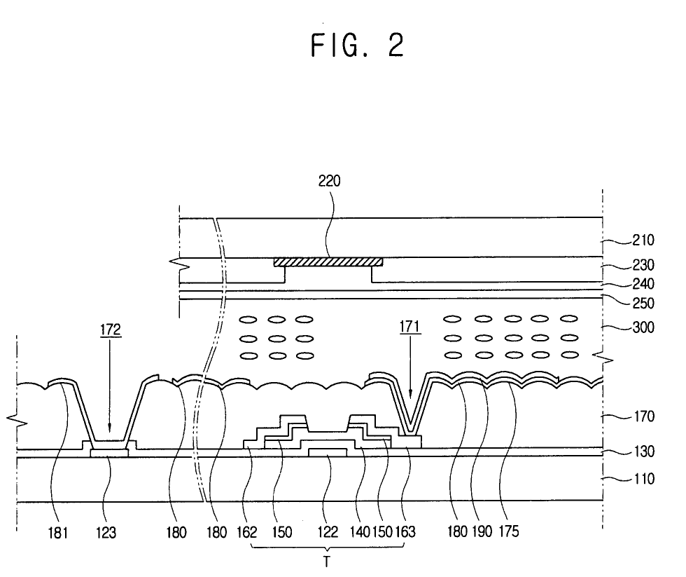

In the following description, if a layer is said to be formed ‘on’ another layer, then a third layer may be disposed between the two layers or the two layers may be contacted with each other. In other words, it will be understood that when an element such as a layer, film, region, or substrate is referred to as being “on” another element, it can be directly on the other element or intervening elements may also be present. Further, if a layer is said to be formed ‘directly on’ another layer, then the two layers are contacted with each other. FIG. 1 is a view showing an arrangement of a thin film transistor substrate according to an embodiment of the present invention, and FIG. 2 is a sectional view taken along line II-II in FIG. 1.

In the ensuing description, a liquid crystal display device is illustrated as one example among the various flat display devices. However, the present invention is not limited thereto and is applicable to other flat display device such as an organic light emitting diode device (OLED), a plasma display panel (PDP) and the like. In addition, in the embodiment of the present invention, although the transflective type liquid crystal display device is described as one example, the present invention is applicable to the reflection type liquid crystal display device.

A liquid crystal display device 1 according to the present invention comprises a liquid crystal panel. The liquid crystal panel comprises a thin film transistor substrate 100 (hereinafter, referred to as “first substrate) provided with a thin film transistor (TFT) for controlling and driving each pixel, a color filter substrate 200 (hereinafter, referred to as “second substrate”) facing and attached to the first substrate 100, and a liquid crystal layer 300 located between the substrates 100 and 200.

The first substrate 100 comprises a first insulating substrate 110; a plurality of gate wires 121, 122 and 123 and a plurality of data wires 161, 162, 163 and 164 formed on the first insulating substrate 110 in the form of a matrix; a thin film transistor (TFT) T which is a switching element formed at an intersection portion of gate wires 121, 122, 123 and data wires 161, 162, 163, 164; and a pixel electrode 180 connected to the thin film transistor T. A signal voltage is applied to the liquid crystal layer 300 formed between pixel electrode 180 and a common electrode 250 of the color filter substrate 200 (to be described below) through the thin film transistor T. The molecules of the liquid crystal layer 300 are arranged according to the applied signal voltage, varying the light transmissivity of the liquid crystal layer.

A substrate made of insulating material such as glass, quartz, ceramic or plastics or the like can be used as the first insulating substrate 110. The first insulating substrate 110 may be made of a plastic material to make the liquid crystal display device 1 flexible. Suitable plastic material may include polycarbonate, polyimide, polynorborene (PNB), polyether sulfone (PES), polyarylate (PAR), polyethylenaphthalate (PEN) or polyethylene terephthalate (PET). The first insulating substrate 110 is divided into a display region on which an image is formed and a peripheral region disposed around the display region. Various lines and the thin film transistor described below are provided on the display region.

Gate wires 121, 122 and 123 are formed on the first insulating substrate 110. Gate wires 121, 122 and 123 may be one-layered or multiple-layered. Gate wires 121, 122 and 123 comprises the gate line 121 extended in a transverse direction, a gate electrode 122 connected to the gate line 121 and a gate pad 123 provided at an end portion of the gate line 121 and connected to a gate driving circuit (not shown) for receiving a driving signal.

A gate insulating layer 130 made of silicon nitride (SiNₓ) and the like covers gate wires 121,122 and 123.

A semiconductor layer 140 made of a semiconductor such as amorphous silicon and the like is formed on the gate insulating layer 130, and an ohmic contact layer 150 made of n+ hydrogenated amorphous silicon doped with n type impurity with high concentration are formed on the semiconductor layer 140. A portion of the ohmic contact layer 150 corresponding to a channel section formed between the source electrode 162 and the drain electrode 163 is removed.

Data wires 161, 162, 163 and 164 are formed on the ohmic contact layer 150 and the gate insulating layer 130. Data wires 161, 162, 163 and 164 may also be one-layered or multi-layered and comprise metal. Data wires 161, 162, 163 and 164 comprises a data line 161 formed in the lengthwise direction and intersecting the gate line 121 to form the pixel, a source electrode 162 which is a branch of the data line 161 and extended to an upper side of the ohmic contact layer 150, the drain electrode 163 separated from the source electrode 162 and contacted with an upper portion of the ohmic contact layer 150 formed at an opposite side of the source electrode 162, and the data pad 164 provided at an end portion of the data line 161 and connected to the data driving circuit (not shown) for receiving an image signal.

A passivation layer 170 is formed on data wires 161, 162, 163 and 164 and a portion of the semiconductor layer 140 which is not covered with data wires 161, 162, 163 and 164.

A concave-convex pattern 175, a drain contact hole 171 through which the drain electrode 163 is exposed, a gate pad contact hole 172 connecting the gate line 121 to the gate driving circuit (not shown) for applying a driving signal to the gate line 121, and a data pad contact hole 173 connecting the data line 161 to the data driving circuit (not shown) for applying a driving signal to the data line 161 are formed in passivation layer 170. The concave-convex pattern 175 formed on a surface of passivation layer 170 is provided such that the concave-convex pattern 175 corresponds to the display area of the first insulating substrate 110 and formed for causing light scattering to increase a reflecting efficiency and enhance a reflectance of the light toward the front. Here, to secure a reliability of the thin film transistor T, an inorganic insulating layer such as a silicon nitride layer can be formed between passivation layer 170 and the thin film transistor T.

Pixel electrode 180 is formed on passivation layer 170 on which the concave-convex pattern 175 is formed. Typically, pixel electrode 180 is formed from transparent conductive material such as indium tin oxide (ITO) or indium zinc oxide (IZO). Pixel electrode 180 is connected electrically to the drain electrode 163 through the drain contact hole 171. Contact subsidiary layers 181 and 182 are formed on the gate pad contact hole 172 and the data pad contact hole 173, respectively. In general, the contact subsidiary layers 181 and 182 are also formed from transparent conductive material such as indium tin oxide (ITO) or indium zinc oxide (IZO). A concave-convex pattern is formed on pixel electrode 180 by the underlying concave-convex pattern 175.

A reflective layer 190 is formed on an upper surface of pixel electrode 180. Here, the pixel area formed by the gate line 121 and the data line 161 is divided into a light-transmitting area on which the reflective layer 190 is not formed and a reflective area on which the reflective layer 190 is formed. The light emitted from a backlight unit (not shown) is penetrated through the light-transmitting area on which the reflective layer 190 is not formed and then radiated to an outside of the liquid crystal panel 10, the light radiated from an outside is reflected on the reflective area on which the reflective layer 190 is formed and then radiated again to an outside of the liquid crystal panel 10. The reflective layer 190 may be formed of aluminum or silver, and may be formed of a double-layered structure of aluminum layer/molybdenum layer. The reflective layer 190 is formed on pixel electrode 180. In another embodiment, the reflective layer 190 may not formed in the drain contact hole 171. A concave-convex pattern is formed on the reflective layer 190 by the underlying concave-convex pattern formed on a surface of pixel electrode 180.

Below, the second substrate 200 is described. Black matrixes 220 are formed on the second insulating substrate 210. The second insulating substrate 210 is divided into a display region on which an image is formed and a peripheral region provided around the display region. The black matrix 220 and a color filter 230 described below are provided on the display region. The black matrix 220 generally divides the red-colored filter, the green-colored filter and the blue-colored filter and blocks the light radiated directly to the thin film transistor T formed on the first substrate 100. In general, the black matrix 220 is made from a photosensitive organic material containing black pigment. Carbon black or titanium oxide is used as the black pigment

Color filter 230 comprises repeatedly arranged red-colored filters, green-colored filters and blue-colored filters. The color filter 230 converts the light radiated from the backlight unit (not shown) and penetrated through the liquid crystal layer 300 to a colored light. In general, the color filter 230 is made from a photosensitive organic material.

An overcoating layer 240 is formed on the color filter 230 and a portion of the black matrix 220 which is not covered with the color filter 230. The overcoating layer 240 is formed for planarizing the color filter 230 and protecting the color filter 230. The overcoating layer 240 generally comprises an acrylic epoxy material.

Common electrode 250 is formed on the over coating layer 240. The common electrode 250 is formed from transparent conductive material such as indium tin oxide (ITO) or indium zinc oxide (IZO). The common electrode 250 and pixel electrode 180 apply the voltage to the liquid crystal layer 300.

A liquid crystal is disposed between the first substrate 100 and the second substrate 200 to form the liquid crystal layer 300. The substrates 100 and 200 are bonded to each other by sealant (not shown).

Below, the method for manufacturing the liquid crystal display device according to one embodiment of the present invention is described mainly explaining the method for manufacturing a thin film transistor substrate.

First, as shown in FIG. 1 and FIG. 2, a gate wires forming layer is deposited on the first insulating substrate 110 and patterned through a photolithography process using a mask to form gate wires 121, 122, 123 including the gate line 121, the gate electrode 122 and the gate pad 123. Then, the gate insulating layer 130, the semiconductor layer 140 and the ohmic contact layer 150 are formed sequentially.

Then, the semiconductor layer 140 and the ohmic contact layer 150 are photolithographed to form the semiconductor layer 140 on the gate insulating layer 130 formed on the gate electrode 122. Here, the ohmic contact layer 150 is formed on the semiconductor layer 140.

Then, data wires forming layer is deposited and patterned through a photolithography process using a mask to form the date wires 161, 162, 163 and 164 including the data conductor 161 intersecting the gate line 121, the source electrode 162 connected to the data line 161 and extended to an upper side of the gate electrode 122, the drain electrode 163 faced to the source electrode and the data pad 164 provided at an end portion of the data line 161. Next, a portion of the ohmic contact layer 150 which is not covered with the date wires 161, 162,163 and 164 is etched, and so the ohmic layer 150 is divided into two parts with the gate electrode 122 as a center and a portion of the semiconductor layer 140 is exposed therebetween. In this process, almost all of the ohmic layer 150 is removed and some of the semiconductor layer 140 is etched. It is preferable to carry out an oxygen plasma treatment process to stabilize an exposed surface of the semiconductor layer 140.

Next, passivation layer 170 is formed through a spin coating or a slit coating. At this time, in order to secure the reliability of the thin film transistor T, an inorganic insulating layer such as a silicon nitride layer can be further formed between the passivation 170 and the thin film transistor T.

Here, passivation layer 170 may comprise polymer and can be cured by heat and/or ultraviolet rays.

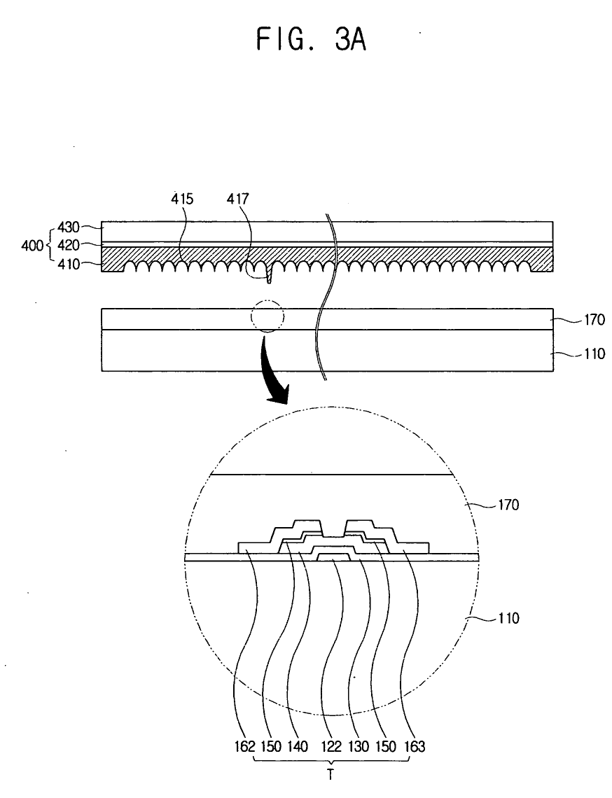

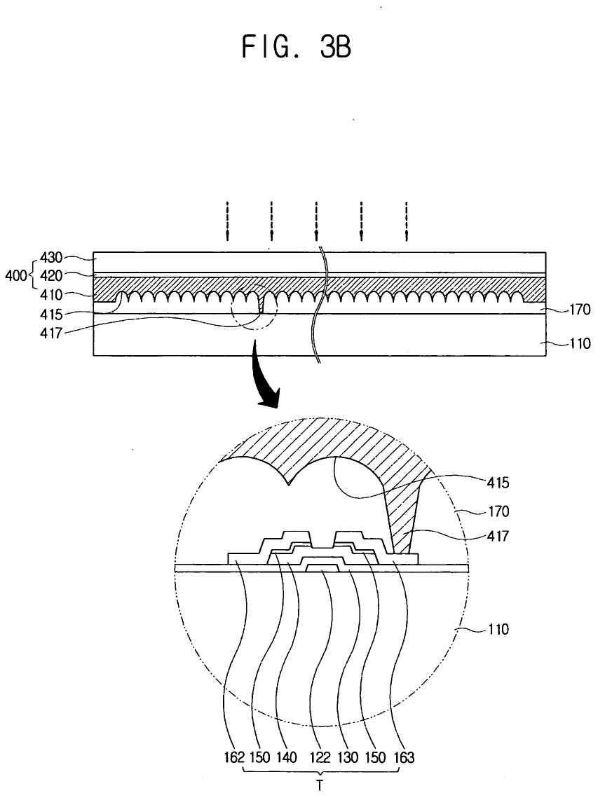

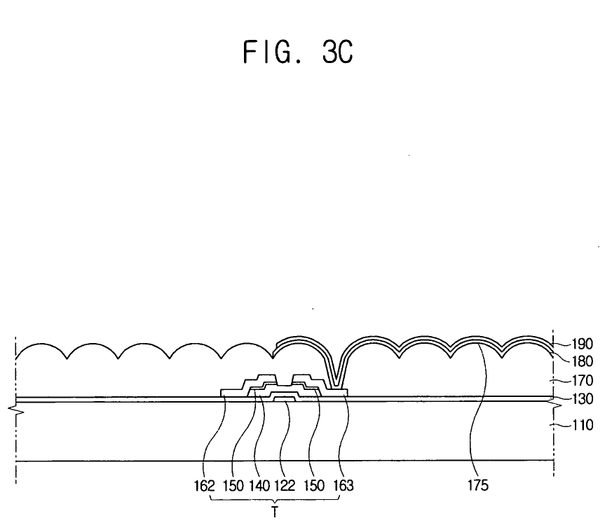

Subsequently, as shown in FIG. 3a, a mold 400 is arranged and disposed on passivation layer 170. The mold 400 is provided with concaves-convexes 415 corresponding to the display region. The concaves-convexes 415 of the mold 400 may be provided to correspond to each pixel area or may be provided to correspond to the entire surface of the display region regardless of the pixel area. The mold 400 is arranged and disposed such that the concaves-convexes 415 face passivation layer 170.

The mold 400 used in the method for manufacturing the liquid crystal display device according to the present invention comprises a supporting layer 420, a pattern forming layer 410 provided on one surface of the supporting layer 420 and having the concaves-convexes 415 formed thereon and a buffer layer 430 formed on the other surface of the supporting layer 420. The pattern forming layer 410 further comprises a protrusion part 417 formed on and protruded from the surface on which the concaves-convexes 415 are formed.

The concaves-convexes 415 are formed on surface of the pattern forming layer 410. A concave-convex pattern 175 corresponding to the concaves-convexes 415 is formed on passivation layer 170 by the concaves-convexes 415. The protrusion part 417 of the pattern forming layer 410 forms the drain contact hole 171 through which at least portion of the drain electrode 163 is exposed. It is desirable that the protrusion part 417 has a height such that the end of the protrusion part 417 and the drain electrode 163 come in contact with each other when the mold 400 is pressurized. The pattern forming layer 410 is made from soft material so as to make the mold 400 contact uniformly with passivation layer 170 and so that mold 400 can be used repeatedly. In addition, the pattern forming layer 410 may be made from material through which ultraviolet rays can penetrates and may be made of PDMS (polydimethylsiloxane).

The supporting layer 420 reduces the difficulty of releasing the mold 400 from passivation layer 170 caused by the characteristics of the material of the pattern forming layer 410 and the deformation of the shape of the pattern forming layer 410 when the mold 400 is released. Since the deformation of the mold 400 is minimized by the supporting layer 420, the misalignment of the mold 400 and damage to the shape of the concave-convex pattern 175 are reduced. The supporting layer 420 may be a film comprising at least one of polyethylene terephthalate (PET) and polycarbonate (PC).

Since the material used for forming the pattern forming layer 410 has the coefficient of thermal expansion which differs from that of material used for forming the supporting layer 420, the shape of the mold 400 may be deformed into a dish shape or an overturned dish shape. The buffer layer 430 prevents the shape of the mold 400 from being deformed. When different materials are in a surface contact in the mold 400 and heat is applied to the mold 400, the shape of the mold 400 is deformed since the materials have different coefficients of thermal expansion. If the coefficient of thermal expansion of the lower layer is larger than that of the upper layer, the shape of the mold 400 is deformed into a dish shape. If the coefficient of thermal expansion of the lower layer is smaller than that of the upper layer, a shape of the mold is deformed into an overturned dish shape. Due to such deformation, the reproducibility and yield of the concave-convex pattern 175 becomes poor. Further, the end portion of the protrusion part 417 may not make contact with the drain electrode 163 so that a contact failure occurs or an additional subsequent process for removing the remained layer is required to be performed. The buffer layer 430 reduces the deforming force, which is caused by the difference between the coefficients of thermal expansion of the pattern forming layer 410 and the supporting layer 420 and makes the degree of lateral expansion of the layers 410 and 420 different, so that the shape deformation of mold 400 is reduced.

It is desirable that the pattern forming layer 410 and the buffer layer 430 are formed from materials which have substantially the same coefficient of thermal expansion and modulus of elasticity so as to minimize deformation of the shape of mold 400. The thickness of the buffer layer 430 can be determined in inverse proportion to the coefficient of thermal expansion of the pattern forming layer 410. That is, if a coefficient of thermal expansion of the pattern forming layer 410 is smaller than that of the buffer layer 430, it is possible to minimize shape deformation of the mold 400 by increasing the thickness of the buffer layer 430. Here, in order to minimize shape deformation of the mold 400, a value obtained from multiplying the thickness by the coefficient of thermal expansion of the buffer layer 430 can be 80% to 120% of the value obtained from multiplying the thickness by the coefficient of thermal expansion of the pattern forming layer 410. The buffer layer 430 can be formed of transparent material through which ultraviolet rays can penetrate. For one example, polydimethylsiloxane (PDMS) may be used for forming the buffer layer 430.

As shown in FIG. 3B, the mold 400 is pressurized toward passivation layer 170 to form the concave-convex pattern 175 on the surface of passivation layer 170. The mold 400 and the first insulating substrate 110 may be pressurized against each other. When the mold is pressurized, light and heat is applied to cure passivation layer 170 during pressurizing. The passivation layer 170 may contain a thermo-initiator or a photo-initiator.

Then, as shown in FIG. 3C, the mold 400 is removed. Since the mold 400 comprises the supporting layer 420, it is easy to release the mold 400 from passivation layer 170. Since the mold comprises the buffer layer 430, the deformation of the mold 400 shape is minimized. Accordingly, the reproducibility and yield of the concave-convex pattern 175 are improved. Since the shape deformation of the mold 400 is minimized, the end portion of the protrusion part 417 make contact with the drain electrode 163 to accurately and reliably form drain contact hole 171 through which the drain electrode 163 is exposed. Passivation layer 170 does not remain on the drain electrode 163 so that contact failure does not occur thereby eliminating the need for a subsequent process to remove a portion of the passivation layer. Here, a mold release agent may be applied on a surface of the mold 400.

After providing passivation layer 170 on which the concave-convex pattern 175 is formed, ITO or IZO is deposited on passivation layer 170 and photolithographed to form pixel electrode 180 which is connected to the drain electrode 163 through the drain contact hole 171. Pixel electrode 180 has a concave-convex pattern formed by the underlying concave-convex pattern 175 of passivation layer 170. At the same time, the contact subsidiary layers 181 and 182, which are connected to the gate pad 123 and the data pad 164 through the gate pad contact hole 172 and the data pad contact hole 173, respectively, are formed.

After pixel electrode 180 is formed, a reflective layer forming layer is deposited on pixel electrode 180 and patterned to form the reflective layer 190. Silver, chrome or alloy thereof can be used for the reflective layer 190. However, an aluminum layer or a double layered structure comprising an aluminum/molybdenum layer can be used as the reflective layer 190. The reflective layer 190 is formed on the reflective area and is not formed on the light-transmitting area. The reflective layer 190 also has a concave-convex pattern formed by the concave-convex pattern 175 as described above. The reflective layer 190 receives the electrical signal through pixel electrode 180 and this signal is transmitted to the liquid crystal layer 300 disposed on the reflective layer 190.

Then, an alignment film (not shown) is formed to provide the thin film transistor substrate 100 according to the embodiment of the present invention.

The black matrix 220, the color filter 230, the overcoating layer 240, the common electrode 250 and the alignment film (not shown) are formed on the second insulating substrate 210 by the known method to complete the second substrate 200. The first and second substrates 100 and 200 provided as described above are bonded to each other and the liquid crystal is injected into a gap between two substrates 100 and 200 to complete the liquid crystal panel 1.

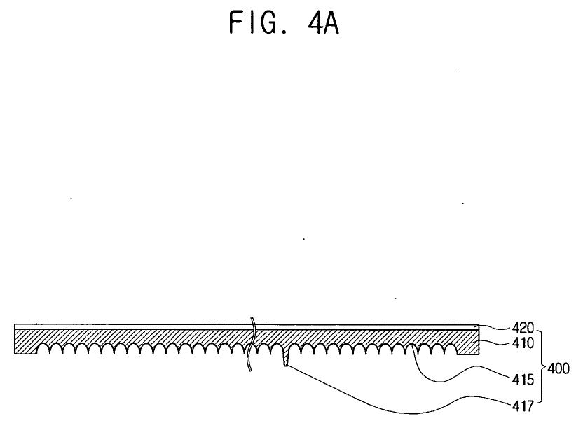

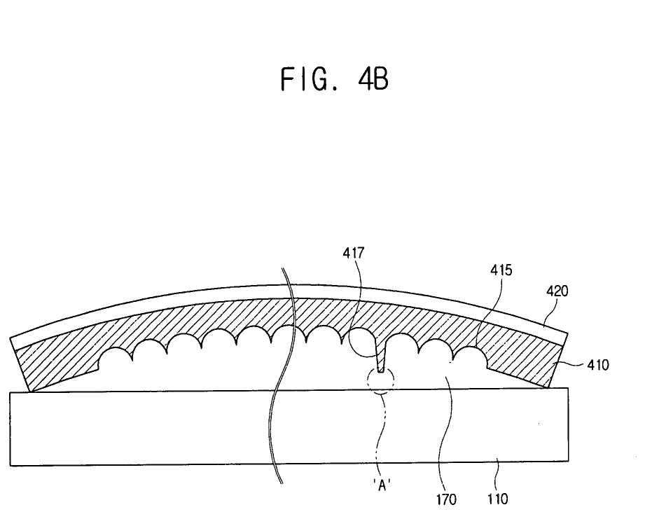

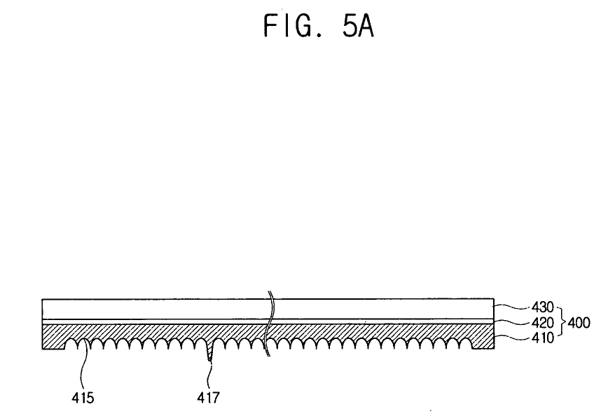

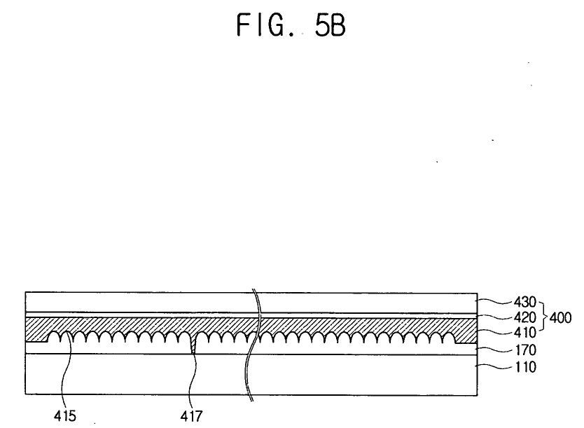

Hereinafter, the mold for manufacturing the liquid crystal display device according to another purpose of the present invention is described. FIG. 4a and FIG. 4b are sectional views of the conventional mold used for manufacturing the liquid crystal display device, and FIG. 5a and FIG. 5b are sectional views of a mold used for manufacturing the liquid crystal display device according to the embodiment of the present invention.

As shown in FIG. 4A, the conventional mold 400 comprises the pattern forming layer 410 on which the concaves-convexes 415 are formed and the supporting layer 410 formed on the pattern forming layer 410. The pattern forming layer 410 further comprises the protrusion part 417 formed on and protruded from one surface on which the concaves-convexes 415 are formed.

The mold 400 as described above is arranged and disposed on passivation layer 170 and then pressurized to form the concave-convex pattern 175 on passivation layer 170. As shown in FIG. 4B, however, in the conventional mold 400, since the pattern forming layer 410 is face-to-face contacted with the supporting layer 420 and the materials used for forming both layers 410 and 420 have coefficients of thermal expansion which differ from each other, a shape of the mold 400 is deformed when heat is applied. If the coefficient of thermal expansion of the pattern forming layer 410 which is a lower layer is lager than that of the supporting layer 420, a shape of the mold 400 is deformed into a dish shape, and if the coefficient of thermal expansion of the pattern forming layer 410 is smaller than that of the supporting layer 420, the shape of the mold 400 is deformed into an overturned dish shape. The above phenomenon is called as the OPD (out of distortion). Due to the OPD, passivation layer 170 corresponding to a central portion of the mold 400 differs from other portion thereof corresponding to an edge portion of the mold 400 in the thickness. Due to such shape deformation of the mold 400, the reproducibility and yield of the concave-convex pattern 175 becomes poor. Also, as indicated the section “A” in FIG. 4b, an end portion of the protrusion part 417 is not contacted with the drain electrode 163 so that a contact failure is generated or an additional subsequent process for removing the remained layer should be performed.

Accordingly, in order to solve above mentioned problems, the present invention provides an improved structure of the mold 400 which can minimize a shape deformation. As shown in FIG. 5, the mold 400 according to the present invention comprises the supporting layer 420, the pattern forming layer 410 provided on one surface of the supporting layer 420 and having the concaves-convexes 415 formed thereon and the buffer layer 430 formed on the other surface of the supporting layer 420. The pattern forming layer 410 further comprises the protrusion part 417 formed on and protruded from one surface on which the concaves-convexes 415 are formed.

The concaves-convexes 415 are formed on one surface of the pattern forming layer 410 and the concave-convex pattern 175 corresponding to the concaves-convexes 415 is formed on passivation layer 170 by the concaves-convexes 415. Here, concaves-convexes 415 can be formed into a concave lens shape, a convex lens shape, or an embossing shape. The protrusion part 417 of the pattern forming layer 410 is formed for forming the drain contact hole 171 through which at least portion of the drain electrode 163 is exposed. It is desirable that the protrusion part 417 is provided such that an end of the protrusion part 417 and the drain electrode 163 come in contact with each other when the mold 400 is pressurized. The pattern forming layer 410 is made from soft material so as to make the mold 400 contact uniformly with passivation layer 170 and to use the mold 400 repeatedly. In addition, the pattern forming layer 410 can be made from material through which ultraviolet rays can be penetrated and may be made of PDMS (polydimethylsiloxane).

The supporting layer 420 solves the problems that it is difficult to release the mold 400 from passivation layer 170 due to a characteristic of material of the pattern forming layer 410 and a shape of the pattern forming layer 410 is deformed when the mold 400 is released, and so the eproducibility and yield of the concave-convex pattern 175 becomes poor Since a shape deformation of the mold 400 is minimized by the supporting layer 420, a misalignment of the mold 400 and a damage to the shape of the concave-convex pattern 175 are minimized. The supporting layer 420 may be a film comprising at least one of polyethylene terephthalate (PET) and polycarbonate (PC). The supporting layer 420 can be formed from material through which light can be transmitted.

Since material used for forming the pattern forming layer 410 has the coefficient of thermal expansion which differs from that of material used for forming the supporting layer 420, a shape of the mold 400 may be deformed into a dish shape or an overturned dish shape. The buffer layer 430 prevents the shape of the mold 400 from being deformed. According to the present invention, by providing the buffer layer 430 on the supporting layer 420, the buffer layer 430 reduces a deforming force caused by a difference between the coefficients of thermal expansion of the pattern forming layer 410 and the supporting layer 420 and makes the degree of lateral expansion of the layers 410 and 420 different, thus the shape deformation of the mold 400 is minimized. Here, it is desirable that the pattern forming layer 410 and the buffer layer 430 are formed from the materials which have substantially the same coefficient of thermal expansion and modulus of elasticity to minimize a shape deformation of the mold 400. The thickness of the buffer layer 430 can be determined in inverse proportion to the coefficient of thermal expansion of the pattern forming layer 410. That is, if a coefficient of thermal expansion of the pattern forming layer 410 is smaller than that of the buffer layer 430, it is possible to minimize a shape deformation of the mold 400 by increasing a thickness of the buffer layer 430. Here, in order to minimize a shape deformation of the mold 400, a value obtained from multiplying a thickness by a coefficient of thermal expansion of the buffer layer 430 may be 80% to 120% of a value obtained from multiplying a thickness by a coefficient of thermal expansion of the pattern forming layer. The buffer layer 430 can be formed of transparent material through which ultraviolet rays can be penetrated. For one example, polydimethylsiloxane (PDMS) can be used for forming the buffer layer.

Due to the above structure, as shown in FIG. 5b, although the concave-convex pattern 175 is formed on passivation layer 170 by using the mold 400, it is easy to release the mold 400 due to the supporting layer 420 and, a shape deformation of the mold 400 is minimized due to the buffer layer 430. Accordingly, the reproducibility and yield of the concave-convex pattern 175 are enhanced. Further, since a shape deformation of the mold 400 is minimized, an end portion of the protrusion part 417 can be contacted with the drain electrode 163, and so the drain contact hole 171 through which the drain electrode 163 is exposed is formed without remaining layer. Because there is no remaining layer on the drain electrode 163, the contact failure is not generated and a subsequent process for removing a remained layer is not required.

As described above, according to the present invention, a method for manufacturing the liquid crystal display device which can enhance the reproducibility and yield of the concave-convex pattern is provided. Also, the mold for the display device in which a shape deformation is minimized is provided.

Although a few exemplary embodiments of the present invention have been shown and described, it will be appreciated by those skilled in the art that changes may be made in these embodiments without departing from the principles and spirit of the invention.

What is claimed is:

1. A method for manufacturing a display device, comprising;
providing an insulating substrate;
forming a passivation layer on the insulating substrate;
arranging a mold including a supporting layer, a pattern forming layer provided on a first surface of the supporting layer and having concaves-convexes formed thereon and a buffer layer formed on the other surface of the supporting layer so that the pattern forming layer faces the passivation layer; and
pressurizing the mold to form a concave-convex pattern corresponding to the concaves-convexes on the passivation layer.

2. The method for manufacturing the display device according to claim 1, wherein the insulating substrate is divided into a display region on which an image is formed and a peripheral region provided around the display region, and the concaves-convexes pattern are provided on the display region.

3. The method for manufacturing the display device according to claim 2, further comprising forming gate wires extended in a first direction on the insulating substrate and data wires insulatively intersecting the gate wires to define a pixel area before forming the passivation layer; and forming a thin film transistor at the intersection area of the gate wires and the data wires, wherein the concaves-convexes pattern on at least a portion of the pixel area.

4. The method for manufacturing the display device according to claim 3, wherein the thin film transistor comprises a source electrode and a drain electrode spaced apart from the source electrode to define a channel region, the pattern forming layer comprises a protrusion part protruded from a first surface of the pattern forming layer, and an end portion of the protrusion part is contacted with the drain electrode when the mold is pressurized.

5. The method for manufacturing the display device according to claim 3, further comprising forming a pixel electrode on the passivation layer after removing the mold; and forming a reflective layer on at least some portion of the pixel electrode.

6. The method for manufacturing the display device according to claim 1, wherein the passivation layer contains polymer and is cured by at least one of heat and light.

7. The method for manufacturing the display device according to claim 6, wherein the passivation layer is cured when the mold is pressurized.

8. The method for manufacturing the display device according to claim 2, wherein the pattern forming layer and the buffer layer comprise the same material.

9. The method for manufacturing the display device according to claim 2, wherein a coefficient of thermal expansion of the buffer layer is substantially the same as that of the pattern forming layer.

10. The method for manufacturing the display device according to claim 2, wherein a modulus of elasticity of the buffer layer is substantially the same as that of the pattern forming layer.

11. The method for manufacturing the display device according to claim 2, wherein a value obtained from multiplying the thickness of the buffer layer by a coefficient of thermal expansion of the buffer layer is 80% to 120% of a value obtained from multiplying the thickness of the pattern forming layer by a coefficient of thermal expansion of the pattern forming layer.

12. The method for manufacturing the display device according to claim 8, wherein the supporting layer comprises a film comprising at least one of polyethylene terephthalate (PET) and polycarbonate (PC).

13. The method for manufacturing the display device according to claim 9, wherein the mold a transparent material through which light is transmitted.

14. A mold for a display device, comprising:
a supporting layer;
a pattern forming layer provided on a first surface of the supporting layer and having concaves-convexes formed thereon; and
a buffer layer formed on a second surface of the supporting layer.

15. The mold for the display device according to claim 14, wherein the pattern forming layer and the buffer layer comprise the same material.

16. The mold for the display device according to claim 14, wherein a coefficient of thermal expansion of the buffer layer is substantially the same as that of the pattern forming layer.

17. The mold for the display device according to claim 14, wherein a modulus of elasticity of the buffer layer is substantially the same as that of the pattern forming layer.

18. The mold for the display device according to claim 14, wherein a value obtained from multiplying the thickness of the buffer layer by a coefficient of thermal expansion of the buffer layer is 80% to 120% of a value obtained from multiplying the thickness of the pattern forming layer by a coefficient of thermal expansion of the pattern forming layer.

19. The mold for the display device according to claim 16, wherein the concaves-convexes comprise a concave lens shape.

20. The mold for the display device according to claim 16, wherein the concaves-convexes comprise an embossing shape.

21. The mold for the display device according to claim 14, wherein the pattern forming layer further comprises a protrusion part protruded from the surface of the pattern forming layer.

22. The mold for the display device according to claim 15, wherein the supporting layer is a film comprising at least one of polyethylene terephthalate (PET) and polycarbonate (PC).

23. The mold for the display device according to claim 14, wherein the pattern forming layer, the supporting layer and the buffer layer comprise transparent material through which light is transmitted.

24. The mold for the display device according to claim 15, wherein at least one of the pattern forming layer and the buffer layer comprise polydimethylsiloxane (PDMS).
